(19) United States
(12) Patent Application Publication
(10) Pub. No.: US 2014/0003016 A1
(43) Pub. Date: Jan. 2, 2014

(54) BATTERY MONITORING SYSTEM

(71) Applicant: AEES, INC., Farmington Hills, MI (US)

(72) Inventors: Patrick McCabe, Lincoln Park, MI (US); Sandra Nedzlek, Northville, MI (US)

(21) Appl. No.: 13/928,641

(22) Filed: Jun. 27, 2013

Related U.S. Application Data
(60) Provisional application No. 61/664,964, filed on Jun. 27, 2012.

(51) Int. Cl. H05K 1/02

(52) U.S. Cl. CPC H05K 1/0271
USPC 361/776

(57) ABSTRACT

A battery monitoring system for monitoring a state of a battery assembly that includes a connection assembly for electrically coupling a controller to the battery assembly. The connection assembly includes a circuit board having an edge extending from a top surface to a bottom surface. The connection assembly also includes a plurality of terminals each having a first end electrically coupled to the circuit board and a second end electrically coupled to the battery assembly with the second end extending beyond the edge of the circuit board with the plurality of terminals each being resiliently biased against the battery assembly for accommodating relative movement between the battery assembly and said circuit board.

### CROSS REFERENCE TO RELATED APPLICATIONS

The subject application claims priority to U.S. Provisional Application No. 61/664,964, filed on Jun. 27, 2012, entitled “Connection Assembly”, the entirety of which is herein incorporated by reference.

### BACKGROUND OF THE INVENTION

1. Field of the Invention

The subject invention generally relates to battery monitoring systems for an electric vehicle.

2. Description of the Prior Art

A battery electric vehicle (BEV) is a type of electric vehicle (EV) that uses chemical energy stored in rechargeable battery packs (i.e., battery assemblies). BEVs use electric motors and motor controllers instead of internal combustion engines (ICEs) for propulsion. Electric vehicles are energy efficient, environmentally friendly in terms of the release of pollutants associated with their use, offer certain performance benefits in terms of quiet, smooth operation and increased acceleration, and reduce energy dependence.

Battery pack designs for Electric Vehicles (EVs) are complex and vary widely by manufacturer and specific application. However, they all incorporate a combination of several mechanical and electrical component systems that perform the basic required functions of the pack.

The actual battery cells can have different chemistry, physical shapes, and sizes, but in general incorporate many discrete cells connected in series and parallel to achieve the total voltage and current requirements of the pack. The battery pack design also typically includes a battery management system (BMS) that manages the respective battery cells or battery packs.

The present invention is directed to a simple, inexpensive, easy to install battery monitoring system for battery assemblies.

### SUMMARY OF THE INVENTION AND ADVANTAGES

The subject invention provides a battery monitoring system for a battery assembly that includes a connection assembly for electrically coupling a battery assembly to a controller.

The battery assembly includes one or more battery modules with each of the one or more battery modules comprising one or more battery cells and each of the one or more battery cells having a positive battery terminal and a negative battery terminal. The battery assembly also includes a positive bus bar electrically coupled to one or more of the positive battery terminals and a negative bus bar electrically coupled to one or more of the negative battery terminals.

The connection assembly includes a circuit board electrically coupled to the controller with the circuit board having an edge extending between a top surface and a bottom surface. The connection assembly also includes a first terminal having a first end electrically coupled to the circuit board and a second end electrically coupled to the positive bus bar with the second end extending beyond the edge of the circuit board, with the first terminal being resiliently biased against the positive bus bar for accommodating relative movement between the positive bus bar and the circuit board. In addition, the connection assembly also includes a second terminal having a first end electrically coupled to the circuit board and a second end electrically coupled to the negative bus bar with the second end of the second terminal extending beyond the edge of the circuit board, with the second terminal being resiliently biased against the negative bus bar for accommodating relative movement between the negative bus bar and the circuit board.

The subject application also provides the sub-assembly of a connection assembly adapted for electrically coupling to the controller and to each of the battery modules and including each of the connection components as described above.

The connection assembly provides an inexpensive, simple to manufacture, and easy to install solution for electrically connecting the battery assembly to the controller for implementation of a battery monitoring system for the battery assembly that manages the battery modules and individual battery cells.

### BRIEF DESCRIPTION OF THE DRAWINGS

Advantages of the present invention will be readily appreciated, as the same becomes better understood by reference to the following detailed description when considered in connection with the accompanying drawings.

FIG. 1 is a perspective and partially exploded view of a battery monitoring system including a connection assembly, a controller, and a battery assembly of a battery electric vehicle (BEV).

FIG. 2 is an enlarged view from FIG. 1 of the connection assembly included in the battery assembly.

FIG. 3 is a perspective view a battery cell included in the battery assembly.

FIG. 4 is an exploded view of the negative circuit board assembly included in the connection assembly.

FIG. 5 is an exploded view of a portion of the positive circuit board assembly included in the connection assembly.

FIG. 6 is a perspective view of the circuit board of the connection assembly.

FIG. 7 is a perspective view of a portion of the connection assembly including a plurality of terminals extending from the circuit board.

FIG. 8 is a perspective view of the connection assembly including a plurality of headers coupled to the circuit board and a plurality of wire leads extending from each of the headers.

FIG. 9 is a perspective view of one embodiment of the plurality of terminals of the connection assembly.

FIG. 10 is a perspective view of another alternative embodiment of the plurality of terminals on the connection assembly.

FIG. 11 is a perspective view of still another alternative embodiment of the plurality of terminals on the connection assembly.

FIG. 12 is a perspective view of a trace disposed on the circuit board of the connection assembly with a circuit protection device (CPD) integrally formed with the trace and with one of the plurality of terminals coupled to the trace.

FIG. 13 is a perspective view of one of the headers of the connection assembly having one of a plurality of wire leads inserted within one of a plurality of cavities defined by the header.

FIG. 14 is a perspective view of a retainer of the connection assembly for retaining the plurality of wire leads.

FIG. 15 is a perspective view of an alignment pin of the connection assembly for retaining the connection assembly to the battery assembly.

FIG. 16 is a perspective view of a standoff pin of the connection assembly.

FIG. 17 is a perspective view of a gasket of the connection assembly.

FIG. 18 is a perspective view of a thermistor of the connection assembly.

FIG. 19 is a perspective view of the circuit board having a plurality of circuit protection devices (CPD's) mounted to the surface of the circuit board.

FIG. 20 is a perspective view of a portion of the connection assembly in accordance with another embodiment in which the spacing of the plurality of terminals.

### DETAILED DESCRIPTION OF THE PREFERRED EMBODIMENT

Referring to the Figures, wherein like numerals indicate corresponding parts throughout the several views, a battery monitoring system 100 which may be implemented in a battery assembly 22 for battery electric vehicle (BEV) applications is provided.

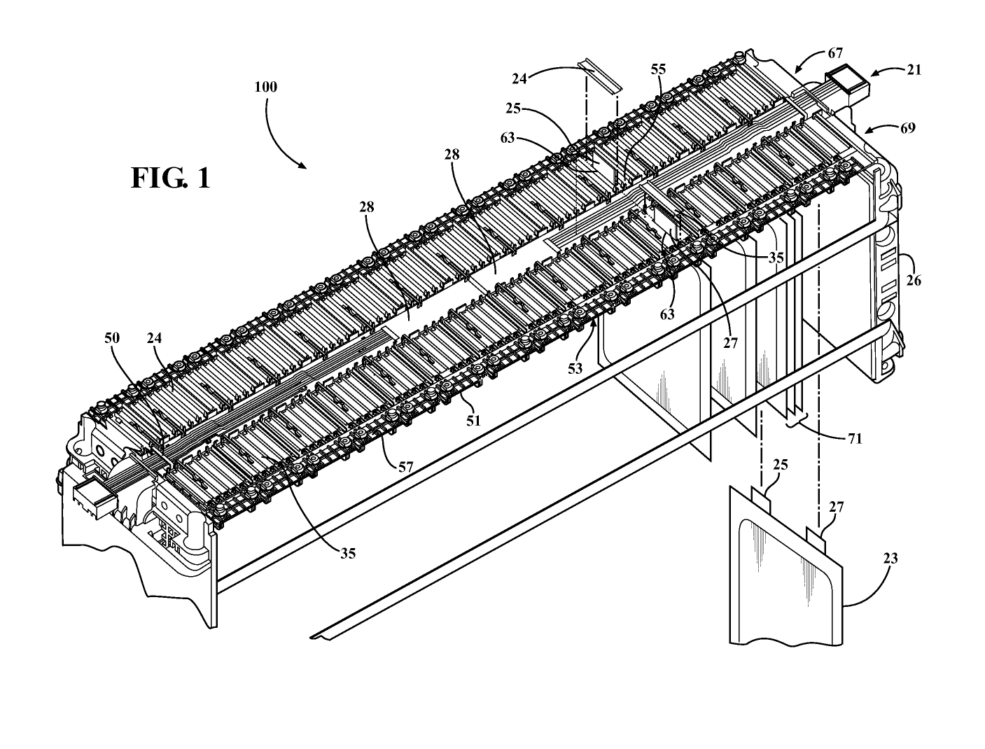

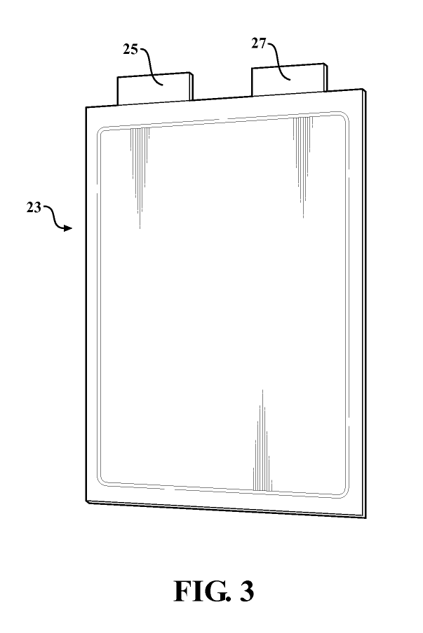

Referring now to FIGS. 1-3, the battery assembly 22 includes one or more battery cells 23, typically lithium ion batteries. As best shown in FIG. 3, the battery cells 23 each include a positive battery terminal 25 and a negative battery terminal 27. The battery cells 23 can have different chemistry, physical shapes, and sizes than the one depicted in representative FIG. 3 and can be organized into one or more battery modules 71.

The battery assembly 22 also includes a non-conductive housing 51 having an inner portion 53 and an outer portion 57. The outer portion 57 includes a plurality of slots 55 preferably organized into a pair of rows 67, 69, wherein the plurality of adjacent slots 55 in a single row 67 or 69 are separated from the next adjacent slot 55 by a raised partition 61. The outer portion 57 of the housing 51 also includes a portion 65 that is centrally located between the respective pairs of rows 67, 69.

Each of the plurality of slots 55 includes one or more openings 63 that extend from the inner portion 53 to the outer portion 57. As best shown in FIG. 1, the battery modules 71 are assembled and contained within an inner portion 53 of a non-conductive housing 51 such that a respective positive terminals 25 or negative terminal 27 extend within a respective one of the one or more openings 63 of each slot 55.

In certain embodiments, the battery modules 71 are assembled and contained within the inner portion 53 of the housing 51 such that each of the positive terminals 24 of each of the respective battery modules 71 extend within the openings 63 along a single row 67 of slots 55 of the housing 51, while the negative terminals 35 of each of the respective battery modules 71 extend within the openings 63 along the other respective row 69 of slots 55. In other embodiments, the battery modules 71 may be assembled such that the positive battery terminals 24 of one or more battery modules 71 extend through the respective openings 63 with a respective slot 55 in row 67, while the positive battery terminals 24 of a one or more additional battery modules 71 may extend through openings 63 of a respective slot 55 in row 69.

As also shown in FIGS. 1, 2, 12 and 20, the battery assembly 22 also includes positive bus bars 24 and negative bus bars 35 that are each individually disposed within a respective slot 55 on the outer portion 57 of the housing 51. Each of the respective disposed positive bus bars 24 is also electrically coupled to the respective one or more positive battery terminals 25 of a single battery module 71 that extends through the respective opening 63. Similarly, each of the respective disposed negative bus bars 35 is also electrically coupled to the respective one or more negative battery terminals 27 of a single battery module 71 that extends through the respective opening 63.

The battery monitoring system 100 also includes a controller 26 disposed adjacent to the one or more battery modules 71. In certain embodiments, the controller 26 is coupled to or otherwise secured to a portion of the housing 51 that is remote from the battery modules 71 and from the connection assembly 21. The controller 26 implements the battery monitoring system 100 for determining and balancing a state of capacity of each of the one or more battery cells 23 within the one or more battery modules 71 and for otherwise monitoring the battery cells 23 and battery modules 71.

The battery monitoring system 100 also includes a connection assembly 21 that may be implemented in the battery system 22. The connection assembly 21 is operatively coupled (i.e., electrically coupled) to each of the one or more positive bus bars 24 and/or to each of the one or more negative bus bars 24 of the battery assembly 22. The connection assembly 21 is also operatively coupled to the controller 26, as will be described below. In implementation of the battery monitoring system 100, electrical current passes between each of the plurality of positive or negative bus bars 24 of the battery assembly 22 and the controller 26 through the connection assembly 21 (i.e., the controller 26 is electrically coupled to the positive or negative bus bars 24 through the connection assembly 21). It is to be appreciated that more than one connection assembly 21 may be coupled between the plurality of positive and negative bus bars 24 of the battery assembly 22 and the controller 26.

As shown best in FIGS. 1, 2, 19 and 20, the connection assembly 21 includes at least one circuit board 28 that is disposed and preferably secured onto the portion 65 of the outer portion 57 of the housing 51 that is centrally located between the rows 67, 69 of the respective slots 55. In still other exemplary embodiments, as opposed to being centrally located on the portion 65 of the housing 51 between the respective rows 67, 69, the at least one circuit board 28 may be coupled to another portion of the outer portion 57 of the housing 51 such that the rows 67, 69 are located between the respective circuit boards 28.

A circuit board 28, as defined herein, is an insulated board on which interconnected circuits and components such as microchips are mounted or etched. In the exemplary embodiments as illustrated in the attached figures, the circuit board 28 is a printed circuit board (PCB) 28. Alternatively, the circuit board 28 may be a printed wire board (PWB), or be an insulated board including one or more bus bars, or comprise any other type of support structure that aids in mechanically and electrically coupling the controller 26 to the battery system 22.

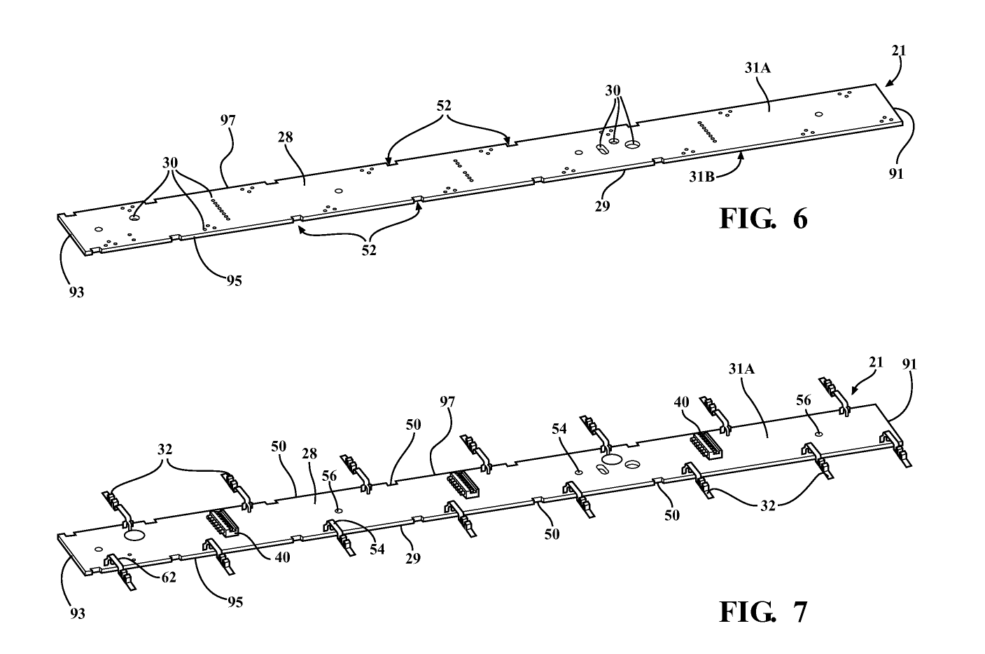

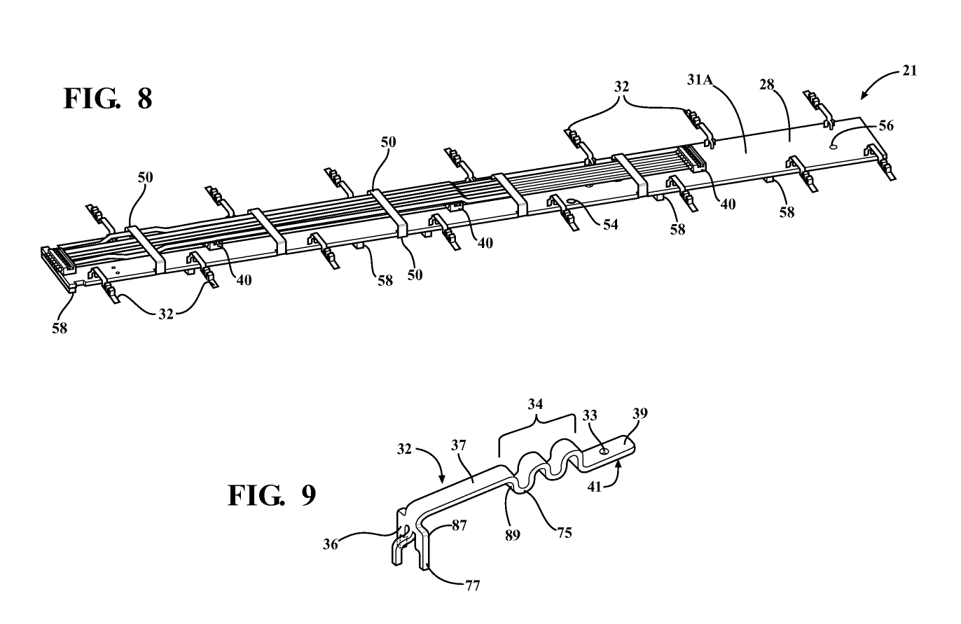

The at least one circuit board 28 typically is elongated such that the at least one circuit board 28 spans a length of the battery assembly 22. As shown best in FIG. 1, the at least one circuit board 28, in certain embodiments, is substantially planar and includes more than one circuit board 28 that span the length of the battery assembly 22. In addition, as best shown in FIGS. 6-8, the circuit board 28 includes an edge 29 that extends from a top surface 31A to a bottom surface 31B of the circuit board 28. The circuit board 28 also includes a top end 91 and a bottom end 93 defining opposing first and second sides 95, 97 of the circuit board 28. The sides 95, 97 may define the outer edge 29 of the circuit board 28 between the top surface 31A and the bottom surface 31B.

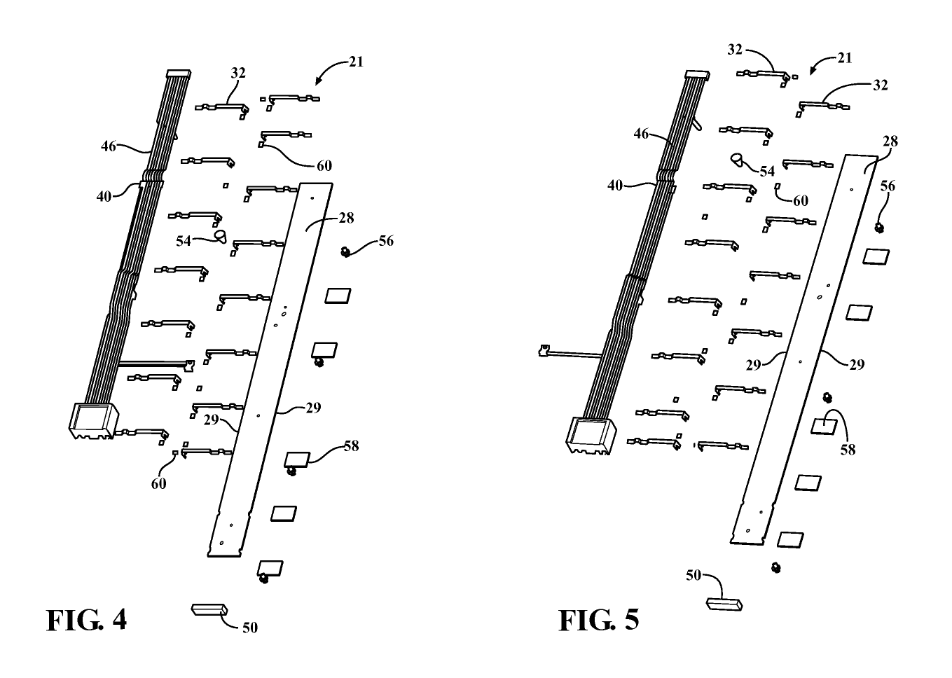

As shown best in FIGS. 4-8 and 20, the circuit board 28 may include a plurality of apertures 30 extending between the opposing surfaces 31A, 31B for permitting various components of the connection assembly 21 to be coupled to the circuit board 28 and for allowing the circuit board 28 to be secured to the housing 51, as will be described below. The circuit board 28 may be conformal coated according to any suitable method for protecting the circuit board 28 and surrounding components from environmental conditions as well as electrical short circuit conditions. While the circuit board 28 shown in FIGS. 4-8 and 20 is illustrated as being generally rectangular in shape along the top surface 31A and bottom surface 31B, the shape may take on many different forms, and include, for example, notches along the opposing first and second sides 95, 97 (such as, for example, the notches 52, as defined further below). The edge 29 that extends from a top surface 31A to a bottom surface 31B, as defined above, would thus follow the alternative shape, including wherein the outer edge 29 follows the respective sides 95, 97 within the notches 52.

As shown generally throughout the Figures, the connection assembly 21 includes one or more terminals 32 for coupling the circuit board 28 to each of the one or more of positive bus bars 24 and negative bus bars 35. Each of the terminals 32 may be spaced from one another along the length of the circuit board 28 according to any suitable distance required and each of the terminals 32 extends beyond the edge 29 of the circuit board 28, such as extending beyond the outer edge 20 of the circuit board from each of the respective sides 95, 97 (such as illustrated in FIGS. 1, 2, 7, 8, 19 and 20) to connect to each of the respective positive bus bars 24 or negative bus bars 35, as will be described in further detail below.

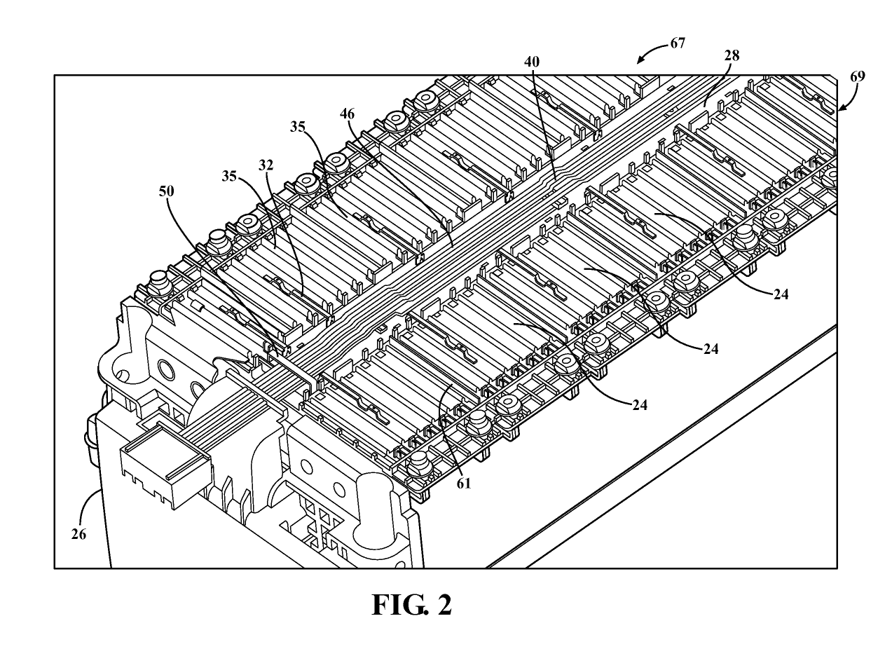

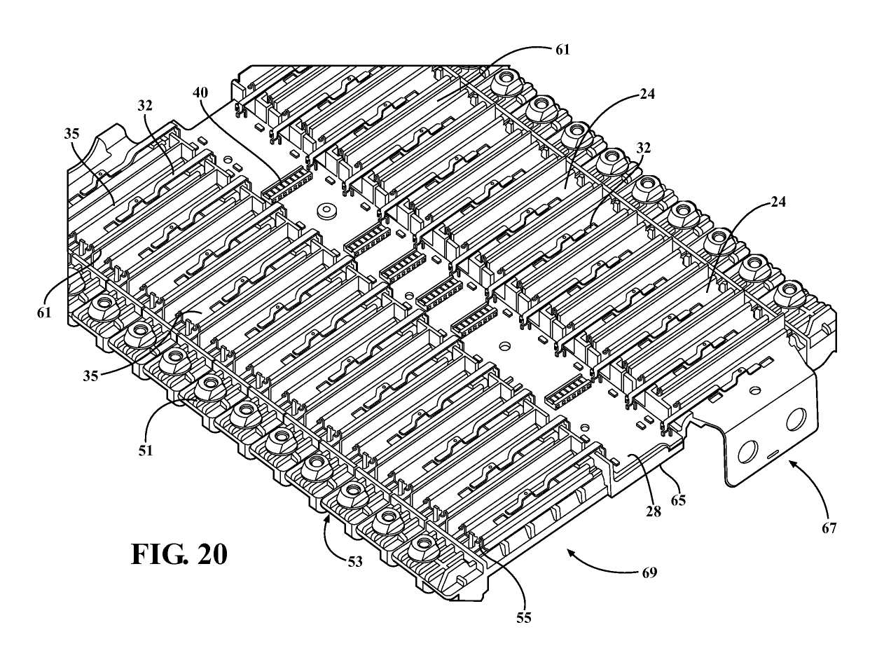

The spacing of the terminals 32 relative to one another along the circuit board 28, as well as the number of battery cells 23 within each battery module 71, as noted above, may vary, depending upon the power requirements for the BEV and other factors. For example, in the alternative embodiments as shown in FIGS. 2 and 20, respectively, the spacing of the terminals 32 and the number of battery cells 23 per battery module 71 as shown in FIG. 2 is greater than the spacing of the terminals 32 and the number of battery cells 23 per battery module 71 as shown in FIG. 20.

Each of the terminals 32 may have any suitable thickness and any predetermined amount of flexibility. In addition, each of the terminals 32 may be compressively biased towards the respective positive bus bar 24 or negative bus bar 35 for applying a force against each respective bus bar 24 or 35 to ensure electrical contact is maintained between a terminal 32 and the respective bus bars 24, 35 during operation. In addition, a secondary securing operation such as welding or mechanical fastening may be used to secure the terminal 32 to the respective bus bar 24 or 35 to prevent separation of the terminal 32 from its respective bus bar 24 or 35.

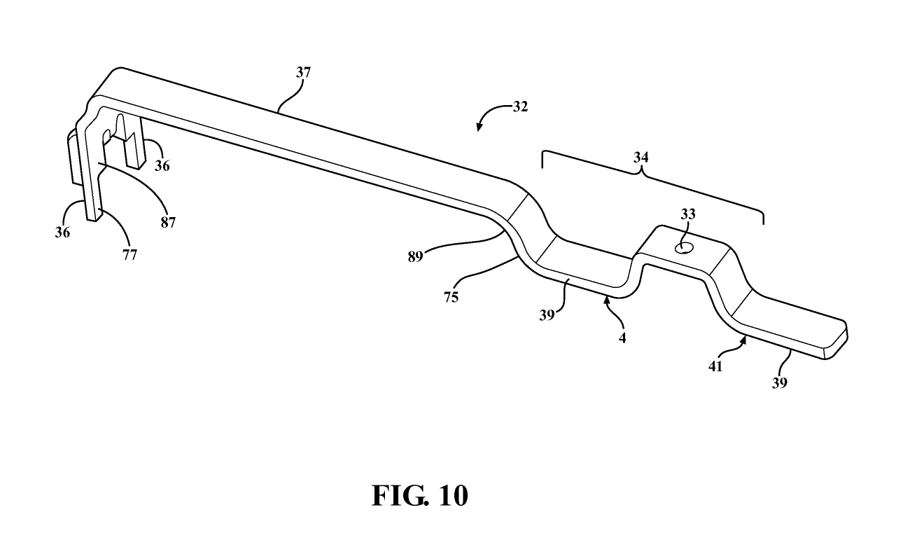

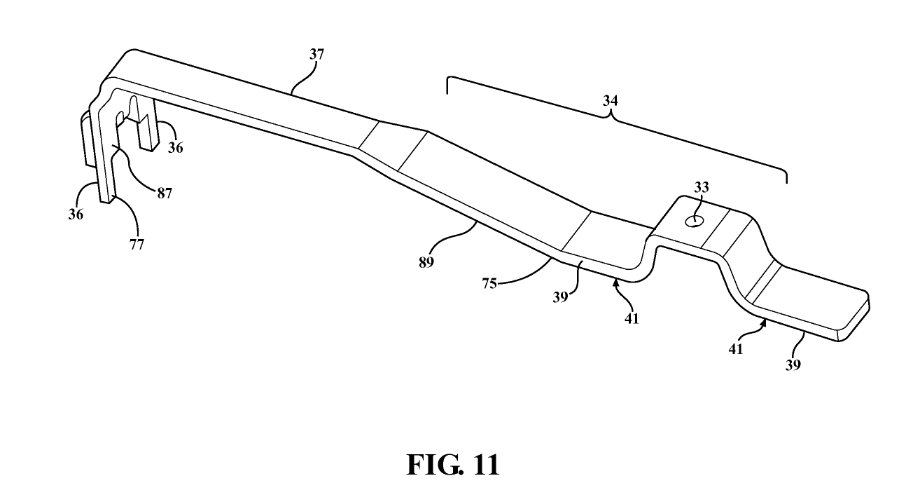

More specifically, as illustrated in FIG. 9-11 in three alternative embodiments, each terminal 32 is configured for allowing the terminal 32 to be compressingly (i.e., resiliently) biased against and flex in response to physical contact with each of the respective bus bars 24 or 35 to which they are coupled. Furthermore, each terminal 32 may include a designated region having reduced material thickness for increasing the flexibility of the terminal 32.

Referring now to the non-limiting exemplary embodiments provided in FIGS. 9-11, each terminal 32 includes a first end 36 and a second end 75 and includes an intermediate region 37 for interconnecting the first end 36 and the second end 65. The intermediate region 37 is configured to resiliently bias the first end 36 relative to the second end 75 for accommodating relative movement between the battery assembly 22 and the circuit board 28. The second end 75 of the terminal 32 extends beyond the edge 29 of the circuit board 28. In the preferred embodiments, the second end 75 also extends over the respective bus bars 24 or 35 to which the terminal 32 it is coupled. The term “extends beyond the edge 29” indicates that the second end 75 of the terminal 32 would not intersect any imaginary line extending normal to any edge 29 of the circuit board 28 (including an outer edge 29 defined along either side 95 or 97) in a direction from the bottom surface 31B to the top surface 31A, or any imaginary line extending perpendicular to any portion of the circuit board 28 (wherein such imaginary lines are parallel to one another), when the terminal 32 is coupled to both the circuit board 28 and respective bus bar 24 or 35. In certain embodiments, the intermediate region 37 is substantially linear along its length between the first end 36 and the second end 75.

In certain embodiments, each terminal 32 includes a first leg 87 coupled to the intermediate region 37 proximate to the first end 36 and a second leg 89 coupled to the intermediate region 37 proximate to the second end 75 for elevating the intermediate region 37 relative to at least one of the circuit board 28 and the battery assembly 22.

In certain other embodiments, each terminal 32 includes one or more corrugations 34 connected to the second leg 89 that aids the intermediate region 37 in resiliently biasing the first end 36 relative to the second end 75 as described above. In addition, the terminal 32 includes one or more contact regions 39 having a bottom surface 41 that contacts the respective bus bar 24 or 35 during operation of the BEV, even in circumstances wherein particular components of the battery assembly 22, such as the battery cells 23, may expand or contract during operation. In certain embodiments, the contact regions 39 define a portion of the one or more corrugations 34.

In certain embodiments, the width of the terminal 32 along the one or more contact regions 39 may be increased relative to the remainder of the terminal 32 such that the area of the bottom surface 41 contacting the respective positive or negative bus bars 24 is correspondingly increased, and hence provides a greater region of electrical contact.

In certain embodiments, each terminal 32 preferably also includes a plurality of prongs 77 at or proximate to the first end 36 connected to the first leg 87 for securing the terminal 32 to the circuit board 28 and for aligning the terminal 32 to respective bus bar 24 or 35 during assembly. Each of the prongs 77 are insertable into the apertures 30 defined by the circuit board 28. Each of the prongs 77 may be coupled to the circuit board 28 according to any suitable method, such as soldering, and the like. In other embodiments, the terminal 32 may be secured to the circuit board 28 by a variety of other methods known to those of skill in the electrical arts.

In certain embodiments, the terminal 32 also includes one or more locater holes 33 along the one or more of the corrugations 34 or along the one or more of the contact regions 39, or both. The locater holes 33 are used to align the laser welding equipment for laser welding the one or more contact regions 39 of the terminal 32 to the respective bus bar 24 or 35.

In operation, electrical current passes from each of the respective bus bars 24 or 35 to its terminal 32 through the contact region 39. As such, the terminals 32 may include any suitable conductive material for conducting electricity. Preferably, each terminal 32 includes copper and/or aluminum at portions of the terminal 32 abutting the respective bus bar 24 or 35. Furthermore, each terminal 32 preferably includes copper at portions of the terminal 32 abutting the circuit board 28, such as at the first end 36 or within the prongs 77. Even more preferably, the conductive material of the terminal 32 is the same as the conductive material of the respective bus bar 24 or 35 to which it is coupled.

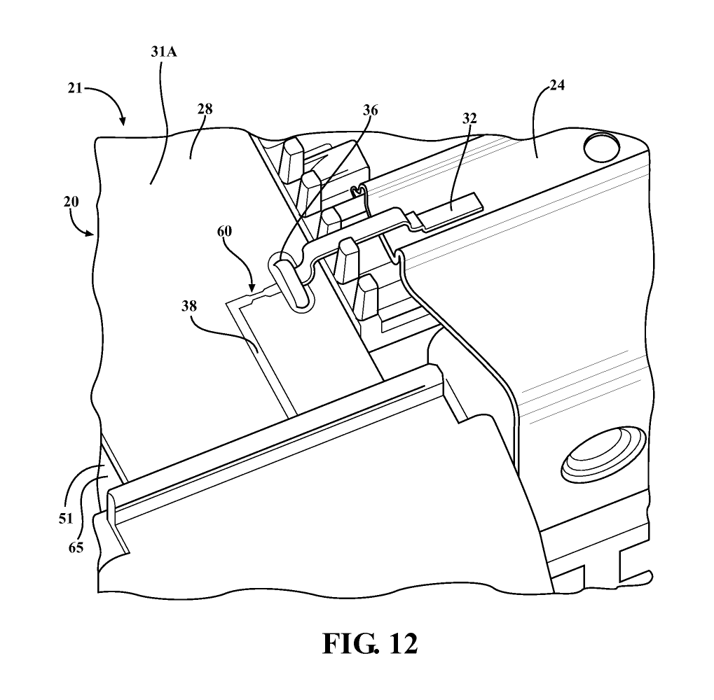

As illustrated in FIG. 12, the connection assembly 21 includes a plurality of traces 38 disposed on the circuit board 28 and electrically coupled to each of the plurality of terminals 32 proximate to the first end 36, and preferably electrically coupled to at least one of the plurality of prongs 77 of the respective terminal 32 proximate to the first end 36. For simplicity of illustration, only one of the plurality of traces 38 is shown in FIG. 12. However, it is to be appreciated that the plurality of traces 38 in the connection assembly 21 are substantially similar to the trace 38 shown in FIG. 12. Electrical current that passes from the respective bus bar 24 or 35 to the respective trace 38 during operation thus passes through the various components of the terminal 32.

The traces 38 include any suitable conductive material for conducting electricity and preferably may be formed from the same conductive material as the contacting portion of the respective terminal 32 to which they are electrically connected. The traces 38 may follow any suitable path on the circuit board 28. In certain embodiments, the traces 38 comprise a metal wire coupled within or running along the surface of the circuit board 28. In certain embodiments, the total number of traces 38 corresponds to the total number of terminals 32.

As shown generally in FIGS. 7, 8, 13, 19 and 20, the connection assembly 21 further includes at least one header 40 coupled to the circuit board 28. Each header 40 may include header prongs 42 for coupling the header 40 to the circuit board 28 and for collecting each of the traces 38 coupled to the terminals 32. The header prongs 42 may be inserted into the apertures 30 defined by the circuit board 28 and coupled to the circuit board 28 according to any suitable method, such as soldering, and the like. Each of the traces 38 may follow a path on the circuit board 28 between the terminal 32 and one of the header prongs 42. Each of the traces 38 are coupled to each of the header prongs 42. As such, electrical current passes between each of the terminals 32 and each of the headers 40 through each of the traces 38. Each header 40 may be spaced from one another along the length of the circuit board 28 according to any suitable distance. Preferably, each header 40 is spaced from one another to optimize the path each trace 38 follows between each terminal 32 and the each header 40.

One of the headers 40 may collect traces 38 corresponding to terminals 32 that are coupled solely to negative bus bars 35. Another one of the headers 40 may collect traces 38 corresponding to terminals 32 that are coupled solely to positive bus bars 24. However, it is to be appreciated that any one header 40 may collect traces 38 corresponding to positive bus bars 24 and negative bus bars 35.

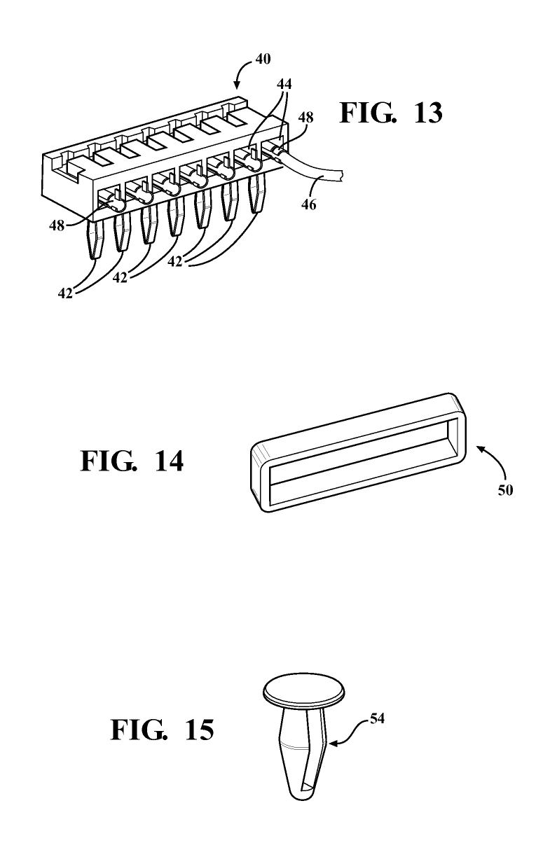

As shown best in FIG. 13, each header 40 further includes cavities 44 for receiving and securing wire leads 46. Specifically, each wire lead 46 includes a wire terminal 48 crimped to the wire lead 46. The wire terminal 48 is insertable within the cavity 44 of the header 40 such that the wire terminal 48 may be secured by the header 40. In implementation of the battery monitoring system 100, electrical current passes between each header 40 and the controller 26 through the wire lead 46. More specifically, each of the wire leads 46 from each header 40 may be collected by a connector configured to be inserted within and connected to the controller 26. As shown in FIGS. 1, 2, 4, 5 and 8, the wire leads 46 passing from each header 40 may rest upon the circuit board 28. Each of the wire leads 46 may include a solid cable, twisted cable, or the like.

In instances where more than one connection assembly 21 is coupled between the plurality of positive and negative bus bars 24 and the controller 26, one of the connection assemblies 21 may be coupled to the other connection assembly 21. More specifically, each of the connection assemblies 21 may include one of the headers 40. Wire leads 46 may pass between the header 40 of one connection assembly 21 and the header 40 of the other connection assembly 21. However, it is to be appreciated that any other suitable form of connection may be established between one of the connection assemblies 21 and the other.

As shown in FIGS. 1, 4, 5, 8 and 14, the connection assembly 21 may include a plurality of retainers 50 for retaining the wire leads 46 passing between each header 40 and the controller 26 and resting upon the circuit board 28. The retainer 50 may have a looped configuration and may be formed of any suitable material, such as elastic material, and the like. As shown best in FIG. 6, the circuit board 28 may define notches 52 along the outer edge 29 of the circuit board 28 for securing each retainer 50. Specifically, each of the notches 52 may be sized to correspond to a width of the retainer 50. Each retainer 50 may be spaced from one another along the length of the circuit board 28 according to any suitable distance required to retain the wire leads 46. Accordingly, each of the notches 52 defined by the circuit board 28 may be spaced from one another along the length of the circuit board 28 to correspond to placement of each retainer 50.

As shown in FIGS. 4, 5, 7, 8, and 15, the connection assembly 21 may further include a plurality of alignment pins 54 for aligning the connection assembly 21 to the housing 51 of the battery assembly 22. In particular, the apertures 30 defined in the circuit board 28 may receive each of the plurality of alignment pins 54. When inserted into each aperture 30 in the circuit board 28, the alignment pin passes through the housing and aligns the circuit board 28 to the battery assembly 22. The alignment pins 54 may have any suitable configuration and may be formed of any suitable material.

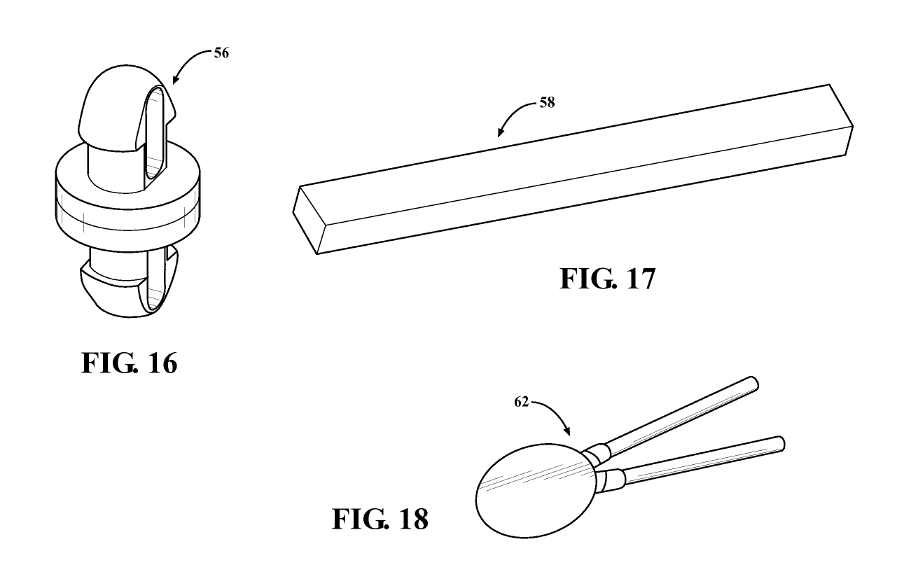

Additionally, the connection assembly 21 may include a plurality of standoff pins 56, as shown in FIGS. 4, 5, 7, 8 and 16. Particularly, each of the standoff pins 56 is coupled to the circuit board 28 and extends from the circuit board 28. The standoff pins 56 secure the connection assembly 21 to the housing 51. More specifically, the standoff pins 56 secure the circuit board 28 of the connection assembly 21 to the housing 51. The standoff pins 56 are preferably installed after the alignment pins 54 align the circuit board 28 to the battery assembly 22.

Furthermore, as shown in FIGS. 4, 5, 8 and 17, the connection assembly 21 may include a plurality of gaskets 58. Each gasket 58 is coupled typically to the circuit board 28, and more specifically, to a side of the circuit board 28 facing the outer portion 57 of the housing 51. The gaskets 58 may be spaced from another along the length of the circuit board 28 according to any suitable distance. The gaskets 58 preferably have a strip-like configuration and may be formed of any suitable material, such as rubber, or the like. The gaskets 58 are typically compressible, and separate the circuit board 28 from direct contact with the outer portion 57 of the housing 51. More specifically, the gaskets 58 reduce impact and provide shock absorption between the circuit board 28 and the housing 51. Accordingly, the gaskets 58 provide strain relief at portions of each terminal 32 abutting the positive and/or negative bus bars 24 and at portions of each terminal 32 abutting the circuit board 28.

As shown in FIGS. 4, 5, 12 and 19, the connection assembly 21 further includes a circuit protection device (CPD) 60 coupled to the circuit board 28. The CPD 60 is preferably a fuse element, although it is to be appreciated that the CPD 60 may also be a circuit breaker, or the like. It is to be appreciated that the connection assembly 21 may include one or a plurality of CPD's 60. The CPD 60 is typically disposed between each of the positive and negative bus bars 24 and the controller 26. Specifically, the CPD 60 may be disposed within the path of each trace 38 to protect the controller 26, the traces 38, and/or the wire leads 46 from over-current conditions.

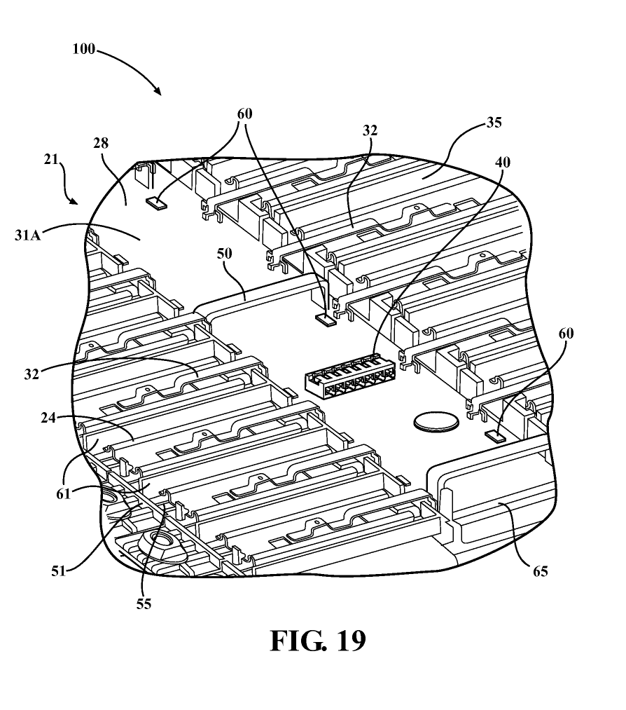

As shown in FIG. 12, the CPD 60 may be integrally formed as part of each trace 38 and aligned in series with each trace 38. That is, part of each trace 38 may be “pinched” thereby defining the CPD 60 therein. Alternatively, the CPD 60 may be inserted into, or mounted and soldered onto the circuit board 28. In such instances, the circuit board 28 may include a fixture for supporting the CPD 60. The fixture may be electrically connected to one of the traces 38 and may interrupt a path of one of the traces 38. The CPD 60 is insertable into the fixture and may be readily removed from the fixture such that the CPD 60 may be easily serviced. Alternatively, as shown in FIGS. 19 and 20, the CPD 60 may be directly inserted into apertures defined on one of the traces 38 of the circuit board 28. Furthermore, the CPD 60 may be included on an insert, which is sized to correspond to one of the apertures 30 defined with the circuit board 28. The aperture 30 defined in the circuit board 28 may interrupt the path of one of the traces 38. As the insert including the CPD 60 is inserted into the aperture 30, the CPD 60 may couple to the trace 38 to complete the path of the trace 38. Such a configuration provides increased ability to replace one CPD 60 for another. The CPD 60 may have any suitable fuse current rating to define the current at which the CPD 60 may open in over-current conditions.

As shown in FIGS. 7 and 18, the connection assembly 21 may further include at least one thermistor 62 for monitoring temperature of and protecting the connection assembly 21. The thermistor 62 may be coupled to at least one of the terminals 32. Specifically, the thermistor 62 may detect temperature changes with respect to one of the terminals 32. Changes in temperature, and specifically, increases in temperature, generally result from heat generated by electrical current flow through the terminal 32. The thermistor 62 may also be coupled to the circuit board 28. Specifically, the thermistor 62 may include wire leads 46 having wire terminals 48 crimped to the wire leads 46. The wire terminals 48 may be inserted into one of the headers 40 to couple electrically the thermistor 62 to the circuit board 28. Accordingly, implementation of the battery monitoring system may include the thermistor 62 because wire leads 46 pass electrical current between one of the headers 40 and the controller 26.

Furthermore, the thermistor 62 may be coupled to at least one of the bus bars 24 for detecting temperature changes with respect to one of the bus bars 24. In such instances, the thermistor 62 may be electrically connected to one of the headers 40 on the circuit board 28. If the temperature rise of one of the bus bars 24 rises to a predetermined level, the thermistor 62 communicates with the battery monitoring system 100 through one of the headers 40 to temporarily disable or power down particular battery cells 23 or battery modules 71 coupled to the respective bus bar 24.

Additionally, the thermistor 62 may be coupled to at least one of the battery cells. The thermistor 62 may be disposed adjacent to battery modules 71 of the battery assembly 22 for measuring temperature changes for battery cells 23 within each respective battery module 71. If the temperature rise of one of the battery cells 23 rises to a predetermined level, the thermistor 62 communicates with the battery monitoring system 100 to temporarily disable or power down the particular battery cell 23 or particular battery module 71.

The thermistor 62 may be coupled to the circuit board 28 and at least one of the terminals 32, bus bars 24 and/or battery cells 23 according to any suitable method, such as affixing to a separate terminal and welding or application of epoxy, and the like. Furthermore, the thermistor 62 may be any suitable type of thermistor 62, such as a negative temperature coefficient (NTC) thermistor 62, or the like.

The connection assembly 21 provides an inexpensive, simple to manufacture, and easy to install solution for fusibly connecting (i.e., electrically coupling) the one or more battery modules 71 of the battery assembly 22 to the controller 26 for implementation of the battery monitoring system 100. The battery monitoring system 100 thus manages the battery modules 71 (and individual battery cells 23) of the battery assembly 22, such as by monitoring its state, calculating secondary data, reporting that data, protecting the battery modules 71 (and individual battery cells 23), controlling the environment of the battery assembly 22, and/or balancing the battery modules 71 or individual battery cells 23 of the battery assembly 22.

While the connection assembly 21 is suitable for use in a battery monitoring system 100 for a battery assembly 22 that includes one or more battery modules 71 having one or more battery cells 23, one of ordinary skill readily recognizes that the connection assembly 21 may find application for use in alternative types of battery assemblies. For example, the connection assembly 21 could be electrically coupled to a battery assembly including commercially available alkaline batteries, such as AAA or AA alkaline batteries.

While the invention has been described with reference to an exemplary embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A battery monitoring system comprising:
a battery assembly comprising:
one or more battery modules with each of said one or more battery modules comprising one or more battery cells and each of said one or more battery cells having a positive battery terminal and a negative battery terminal;
a positive bus bar electrically coupled to one or more of said positive battery terminals;
a negative bus bar electrically coupled to one or more of said negative battery terminals;
a controller for monitoring a status of said battery assembly; and
a connection assembly for electrically coupling said battery assembly to said controller, said connection assembly comprising:
a circuit board electrically coupled to said controller with said circuit board having an edge extending between a top surface and a bottom surface;
a first terminal having a first end electrically coupled to said circuit board and a second end electrically coupled to said positive bus bar with said second end extending beyond said edge of said circuit board, said first terminal being resiliently biased against said positive bus bar for accommodating relative movement between said positive bus bar and said circuit board;
a second terminal having a first end electrically coupled to said circuit board and a second end electrically coupled to said negative bus bar with said second end of said second terminal extending beyond said edge of said circuit board, said second terminal being resiliently biased against said negative bus bar for accommodating relative movement between said negative bus bar and said circuit board.

2. The battery monitoring system according to claim 1, wherein said first terminal includes a first intermediate region interconnecting said first and second ends of said first terminal and resiliently biasing said second end relative to said first end of said first terminal; and wherein said second terminal includes a second intermediate region interconnecting said first and second ends of said second terminal and resiliently biasing said second end relative to said first end of said second terminal.

3. The battery monitoring system according to claim 2, wherein each of said first and second intermediate regions is substantially linear.

4. The battery monitoring system according to claim 2, wherein said first terminal and said second terminal each comprise a first leg coupled to a respective intermediate region proximate said first end and a second leg coupled to said respective intermediate region proximate to said second end for elevating each of said first and said second intermediate regions relative to at least one of said circuit board and said respective bus bar.

5. The battery monitoring system according to claim 4, wherein said first terminal and said second terminal each comprise one or more corrugations connected to a respective second leg at a respective second end.

6. The battery monitoring system according to claim 5, wherein said one or more corrugations define at least one contact region engaging said respective positive or negative bus bar.

7. The battery monitoring system according to claim 1, wherein said circuit board is substantially planar having a top end, a bottom end and said edge defining opposing first and second sides extending between said top and bottom ends, with said first terminal extending beyond said first side and said second terminal extending beyond said second side.

8. The battery monitoring system according to claim 1, wherein said circuit board is centrally located between said positive bus bar and said negative bus bar.

9. The battery monitoring system according to claim 1, wherein said positive bus bar is coupled to a plurality of positive battery terminals with said second end of a single first terminal electrically coupled said positive bus bar.

10. The battery monitoring system according to claim 1, wherein said second end of said first terminal is directly secured to said positive bus bar and wherein said second end of said second terminal is directly secured to said negative bus bar.

11. The battery monitoring system according to claim 1, wherein said connection assembly further comprises;
a first circuit protection device electrically coupled between said controller and said positive bus bar, and
a second circuit protection device electrically coupled between said controller and said negative bus bar.

12. The battery monitoring system according to claim 1, wherein said battery assembly further comprises a non-conductive housing disposed over said one or more battery modules and supporting said positive and negative bus bars, with said housing defining a plurality of openings with said battery terminals extending through said openings into engagement with said bus bars.

13. The battery monitoring system according to claim 12, wherein said non-conductive housing includes a raised partition between each respective bus bar for separating an adjacent pair of said bus bars.

14. A connection assembly for electrically coupling a battery assembly to a controller, said connection assembly comprising:
a circuit board having an edge extending between a top surface and a bottom surface with said circuit board adapted to be electrically connected to the controller;
a plurality of terminals each having a first end electrically coupled to said circuit board and a second end extending beyond said edge of said circuit board for electrical connection to the battery assembly, each of said plurality of terminals having an intermediate region interconnecting said first and second ends and resiliently biasing said second end relative to said first end for accommodating relative movement between the battery assembly and said circuit board.

15. The connection assembly according to claim 14, wherein said intermediate region is substantially linear.

16. The connection assembly according to claim 14, wherein said first terminal and said second terminal each comprise a first leg coupled to a respective intermediate region proximate said first end and a second leg coupled to said respective intermediate region proximate to said second end for elevating each of said first and said second intermediate regions relative to at least one of said circuit board and the battery assembly.

17. The connection assembly according to claim 14, wherein said first terminal and said second terminal each comprise one or more corrugations connected to a respective second leg at a respective second end.

18. The connection assembly according to claim 17 wherein said one or more corrugations define at least one contact region for facilitating the electrical connection to the battery assembly.

19. The connection assembly according to claim 14, wherein said circuit board is substantially planar having a top end, a bottom end and said edge defining opposing first and second sides extending between said top and bottom ends, with said first terminal extending beyond said first side and said second terminal extending beyond said second side.

20. The connection assembly according to claim 14 further comprising a circuit protection device coupled to said circuit board.
